(19) United States
(12) Patent Application Publication
(10) Pub. No.: US 2003/0232276 A1
(43) Pub. Date: Dec. 18, 2003

(54) Fluorinated molecules and methods of making and using same

(76) Inventors: Andrew J. Poss, Kenmore, NY (US); Haridasan K. Nair, Williamsville, NY (US); David Nalewajek, West Seneca, NY (US); Timothy R. Demmin, Grand Island, NY (US)

Correspondence Address: Speciality Chemicals, Honeywell Law Department, 101 Columbia Road, Building Meyer 5, P.O. Box 2245, Morristown, NJ, 07962-2245, US

(21) Appl. No.: 10/371,500

(22) Filed: Feb. 21, 2003

Related U.S. Application Data
(60) Provisional application No. 60/358,592, filed on Feb. 21, 2002.

(51) Int. Cl. G03F 7/038; C08F 10/00; C08F 32/08

(52) U.S. Cl. 430/270.1; 430/311; 526/280; 526/292.1; 560/1

(57) ABSTRACT

Provided are polymers derived from fluoroalkyl norbornenes, fluorinated crotonates, fluorinated allyl alcohols, and combinations of two or more thereof for use in a wide variety of applications, including photoresist compositions. Also provided are methods for producing the fluoroalkyl norbornenes, fluorinated crotonates, and fluorinated allyl alcohols for use in the present polymers.

### FIELD OF INVENTION

The present invention relates generally to polymers derived from fluorinated monomers and the uses of such polymers in lithographic imaging materials, especially photoresist compositions, as well as, dielectric, passivation and insulating materials, light guides, anti-reflective coatings and layers, pellicles, glues and the like. The present invention also relates to novel monomer compounds used for making the polymers of the present invention, and to methods for making such monomer compounds.

### BACKGROUND OF THE INVENTION

Photoresists are organic polymeric materials which find use in a wide variety of applications including use as lithographic imaging materials in semiconductor applications. For example, there is great interest in developing the next generation commercial 157 nm photoresists for a variety of applications in the semiconductor industry. See Chemical and Engineering News, page 23-24, Jul. 15, 2002.

One important property associated with effective photoresists is transparency of the photoresist to light at a given wavelength. Applicants have recognized that although many conventional polymers for optical lithography have demonstrated good performance for use as photoresists at a variety of wavelengths, such polymers nevertheless tend to lack transparency at 157 nmn.

For example, U.S. Pat. No. 5,821,036 describes a method of developing positive photoresists and polymer compositions for use therein. While the disclosed polymer compositions are useful in the method of the '036 patent, such compositions tend to be non-transparent and unusable in 157 nm lithographic methods. U.S. Pat. No. 6,124,074 discloses acid catalyzed positive photoresist compositions which tend to be transparent to 193 nm light but not 157 nm light. U.S. Pat. No. 6,365,322 discloses photoresist compositions for deep UV region (100- 300 nm) that tend to be non-transparent to 157 nm light.

Prior attempts have been made to produce fluorinated polymers that are substantially transparent to light at wavelengths lower than 194 nm, as described above. See, for example, PCT WO 00/67072 and Hoang et al Macromolecules 2002, 35, 6539-6549, and U.S. Pat. Nos. 6,468,712 and 6,486,282. Although initial screening of these polymers shows promise for transparency at 157 nm, applicants have recognized the need for novel polymers which are not only transparent at 157 nm, but also exhibit resistance to plasma, adhesion to a wide range of substances/surfaces, and exceptional mechanical properties in 157 nm lithography applications. Accordingly, the present invention describes the preparation of novel polymers, as well as novel fluorinated monomers for making such polymers, and methods of using such polymers, including, for example, in 157 nm photoresists.

Each of the documents cited above are herein incorporated in their entirety by reference.

### DESCRIPTION OF THE INVENTION AND PREFERRED EMBODIMENTS

According to one aspect, the present invention provides novel fluorinated polymers that can be used to great advantage in a number of applications including, for example, in lithographic imaging materials, especially photoresist compositions, as well as dielectric, passivation and insulating materials, light guides, anti-reflective coatings and layers, pellicles and glues. The preferred polymers of the present invention provide transparency and low optical loss in key areas of the ultraviolet (“UV”) and infrared (“IR”) spectrum, are sensitive to actinic radiation, and are resistant to the reactive environment associated with ion etching. Accordingly, such polymers are particularly suited for use in photoresist applications, as well as other light-sensitive applications. In certain preferred embodiments, the polymers of the present invention comprise one or more repeating units derived from a monomer selected from the group consisting of fluoroalkyl norbornenes, fluorinated crotonates, fluorinated allyl alcohols, and combinations of two or more of these.

According to another aspect, the present invention provides novel monomer compounds that can be advantageously used to form polymers of the present invention.

According to yet another aspect, the present invention provides novel methods for producing monomer compounds for use in producing the polymers of the present invention.

In certain embodiments, the present invention provides a polymer comprising one or more repeating units derived from a monomer selected from the group consisting of fluoroalkyl norbornenes, fluorinated crotonates, fluorinated allyl alcohols, and combinations of two or more of these.

As used herein, the term “fluoroalkyl norbornene” refers generally to a compound described by Formula 1, below:

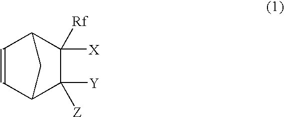

wherein X and Y are independently hydrogen, fluorine, or fluorinated alkyl; R_{f} is a fluorinated alkyl group; Z is —CH₂OH, —CO₂R, or —C(O)R₁; R is an alkyl group; and R₁ is hydrogen, hydroxyl, halogen, or nitrile (—CN).

X, Y, and R_{f} as independently selected fluorinated alkyls may be straight-chain or branched moieties. Examples of suitable fluorinated alkyls include partially or per fluorinated alkyls having from about 1 to about 15 carbon atoms, such as fluoromethyl, difluoromethyl, trifluoromethyl, fluoroethyl, difluoroethyl, trifluoroethyl, tetrafluoroethyl, pentafluoroethyl, fluoropropyl, difluoropropyl, trifluoropropyl, tetrafluoropropyl, pentafluoropropyl, hexafluoropropyl, heptafluoropropyl, fluoroisopropyl, and the like. Any of these moieties may be unsubstituted, or may be further substituted with halogen, hydroxyl, alkoxy aryloxy, alkyl, fluoroalkyl, arylalkyl groups, and the like. A preferred class of fluorinated alkyls includes: fluoromethyl, difluoromethyl, trifluoromethyl, fluoroethyl, difluoroethyl, trifluoroethyl, tetrafluoroethyl, pentafluoroethyl, fluoropropyl, difluoropropyl, trifluoropropyl, tetrafluoropropyl, pentafluoropropyl, hexafluoropropyl, heptafluoropropyl, and the like. A particularly preferred class of fluorinated alkyls includes: trifluoromethyl, pentafluoroisopropyl, and pentafluoroethyl.

R as an alkyl group may be a straight-chain or branched moiety. Examples of suitable alkyls include alkyl groups having from about 1 to about 15 carbon atoms, such as, methyl ethyl, propyl, isopropyl, n-butyl, isobutyl, tert-butyl, n-pentyl, neopentyl, hexyls, heptyls, octyls, nonyls, decyls, undecyls, dodecyls, and the like. Any of these groups may be unsubstituted or may be substituted with halogen, hydroxyl, alkoxy, aryloxy, alkyl, fluoroalkyl, arylalkyl groups, and the like. In a preferred class of alkyls, R is an unsubstituted or substituted: C₁ or C₃-C₈ alkyl. In another preferred class of alkyls, R is an unsubstituted or substituted C₄-C₈ alkyl.

In certain preferred embodiments, the fluoroalkyl norbornene for use in the present invention is a compound of Formula 1 wherein X═R_{f}, Y═R_{f}, or X═Y═R_{f}. In certain other preferred embodiments, Z is —CO₂R or —CH₂OH and X, Y, R_{f} and R are as previously defined. Certain more preferred compounds of Formula 1 comprise compounds wherein Z is —CO₂R or —CH₂OH, and X, Y, R_{f} and R are as previously defined, provided that if X and Y are both hydrogen, and R_{f} is trifluoromethyl, R is not ethyl.

The compounds of Formula 1 may exist in isomeric form. All racemic and isomeric forms of the compounds of Formula 1, including enantiomeric, endo/exo, racemic and geometric isomers and mixtures thereof, are within the scope of the invention. Unless otherwise indicated, all norbornene-derived formulae (such as formulae 1 and 4 below) described herein are intended to cover all racemic and isomeric forms of the compounds/moieties described by such formulae.

Any of a wide range of fluoroalkyl norbornenes can be used according to the present invention in view of the teachings contained herein. Examples of fluoroalkyl norbornenes suitable for use in the present invention include: 2-methylpropyl-3-fluoro-3-(trifluoromethyl)-bicyclo[2.2.1]hept-5-ene-2-carboxylate; 2-methylpropyl-2,3-difluoro-3-(trifluoromethyl)-bicyclo[2.2.1 ]hept-5-ene-2-carboxylate; 2-methylpropyl-2-fluoro-3-(trifluoromethyl)-bicyclo[2.2.1]hept-5-ene-2-carboxylate; 2-methylpropyl-3-(trifluoromethyl)-bicyclo[2.2.1 ]hept-5-ene-2-carboxylate; 3-(trifluoromethyl)-2-hydroxymethyl-bicyclo[2.2.1]hept-5-ene-2-carboxylate; 3-fluoro-3-(trifluoromethyl)-2-hydroxymethyl-bicyclo[2.2.1]hept-5-ene-2-carboxylate; 2-fluoro-3-(trifluoromethyl)-2-hydroxymethyl-bicyclo[2.2.1 ]hept-5-ene-2-carboxylate; and 2,3-difluoro-3-(trifluoromethyl)-2-hydroxymethyl-bicyclo[2.2.1]hept-5-ene-2-carboxylate. Preferred fluoroalkyl norbornenes for use in the present invention include: 2-methylpropyl-2,3-difluoro-3-(trifluoromethyl)-bicyclo[2.2.1 ]hept-5-ene-2-carboxylate; and 2,3-difluoro-3-(trifluoromethyl)-2-hydroxymethyl-bicyclo[2.2.1 ]hept-5-ene-2-carboxylate.

As used herein, the term “fluorinated crotonate” refers generally to a compound described by Formula 2, below:

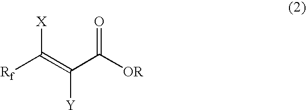

wherein X, Y, R_{f} and R are as previously defined. In certain preferred embodiments, the fluoroalkyl norbornene for use in the present invention is a compound of Formula 2 wherein X═R_{f}, Y═R_{f}, or X═Y═R_{f}.

In view of the teachings contained herein, it is believed that any of the fluorinated crotonates encompassed by this description can be used according to the present invention. Examples of fluorinated crotonates suitable for use in the present invention include: 3,4,4,4-tetrafluoro-but-2-enoic acid t-butyl ester; 2,3,4,4,4-pentafluoro-but-2-enoic acid t-butyl ester; 2,4,4,4-tetrafluoro-but-2-enoic acid t-butyl ester; and 4,4,4-trifluoro-but-2-enoic acid t-butyl ester. Preferred fluorinated crotonates for use in the present invention include 2,3,4,4,4-pentafluoro-but-2-enoic acid t-butyl ester and ethyl-3,3-bis(trifluoromethyl)-2-butenoate.

A variety of fluorinated crotonates for use in preparing the polymers of the present invention are available commercially or are obtainable through art recognized procedures. For example, CF₃C(H)═C(H)CO₂C₂H₅ and (CF₃)₂C═C(H)CO₂C₂H₅ are available commercially from Synquest lab and CF₃(H)C═C(CF₃)CO₂R can be prepared as reported in Duan, J. et al., J. Org. Chem., (1998), 63, 9488-9489. In addition, a number of fluorinated crotonates for use herein can be obtained using synthesis methods of the present invention, described hereinbelow.

As used herein, the term “fluorinated allyl alcohol” refers generally to a compound described by Formula 3, below:

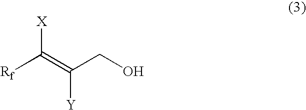

wherein X, Y, and R_{f} are as previously defined. In certain preferred embodiments, the fluoroalkyl norbornene for use in the present invention is a compound of Formula 3 wherein X═R_{f}, Y═R_{f}, or X═Y═R_{f}.

Any of a number of fluorinated allyl alcohols can be used according to the present invention. Examples of fluorinated allyl alcohols suitable for use in the present invention include: 4,4,4-trifluoro-but-2-en-1-ol; 3,4,4,4-tetrafluoro-but-2-en-1-ol; 2,4,4,4-tetrafluoro-but-2-en-1-ol; and 2,3,4,4,4-pentafluoro-but-2-en-1-ol. A preferred fluorinated allyl alcohol for use in the present invention is 2,3,4,4,4-pentafluoro-but-2-en-1-ol.

In certain embodiments, the polymers of the present invention comprise repeating units that are derived from one or more compounds selected from within only one of the types of monomer compounds, i.e., only fluoroalkyl norbornenes, only fluorinated crotonates, or only fluorinated allyl alcohols, of the present invention. In such embodiments, the polymer may be a homopolymer, comprising repeating units all derived from the same compound, or the polymer may comprise two or more repeating units derived from two or more different norbornenes, two or more different crotonates, or two or more different allyl alcohol compounds.

In certain other embodiments, the repeating units of the present polymer are derived from a plurality of compounds of the instant invention, at least two of which are from different types of monomers of the invention. Such compositions may be copolymers, block copolymers, terpolymers, polymers comprising four or more different classes of repeating units, combinations of two or more thereof, and the like.

In yet other embodiments, the polymer of the present invention may include one or more repeating units derived from other monomers, oligomers, or polymer compounds that have been copolymerized with at least one fluorinated crotonate, fluoroalkyl norbornene, and/or fluorinated allyl alcohol of the present invention. Suitable other monomers, oligomers, and polymer compounds include, for example, ethylenically unsaturated compounds, especially those containing at least one fluorine substituent. Preferred ethylenically unsaturated compounds include those defined by the formulae: CF₃CH═CF₂; CF₃CH═CHF; CF₃CF═CHF; CF₃CF═CH₂; CF₂═CH₂; CF₂═CFH; CF₂═CF₂; and R_{pf}CH₂)ₙCV═CVW wherein R_{pf} is a perfluoroalkyl group having from about 1 to about 10 carbon atoms, V and W are indepedently H or F, provided that when R_{pf} is CF₃ and V is F, W must be H.

According to certain preferred embodiments, the polymer of the present invention comprises at least one repeating unit derived from a fluoroalkyl norbornene, the repeating unit being described by the Formula 4, below:

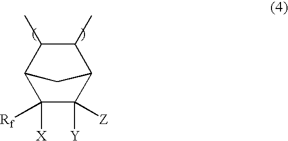

wherein X, Y, R_{f} and Z are as defined above for Formula 1.

The polymers of the present invention are prepared by polymerizing one or more compounds selected from the group consisting of fluorinated crotonates, fluoroalkyl norbornenes, fluorinated allyl alcohols, and combinations of two or more thereof, optionally in the presence of any additional monomer compounds to be copolymerized therewith. Any of a wide range of known methods for polymerizing the present compounds can be used according to the present invention. For example, the monomer compounds may be polymerized via exposure to light or heat and/or through the use of a catalyst. In certain embodiments, the polymers of the present invention are prepared by polymerizing a reaction mixture containing the monomer compounds to be polymerized and a single or multicomponent metal catalyst system as disclosed in the published patent application WO 97/33198 (assigned to B.F. Goodrich and incorporated herein by reference.) The polymers of the present invention can also be prepared, for example, using nickel or palladium catalysts as disclosed in Risse, Makromol Chem., Rapid Commun., vol. 12, pages 255-259 (1991), and Hung, Proceedings of SPIE, vol. 4345, pages 385-395 (2001), both of which are incorporated herein by reference. Other suitable polymerization conditions include those disclosed in Jung, et al., Advances in Resist Technology and Processing XVIII F. M. Houlihan Editor, Proceedings of SPIE Vol.4345 (2001) pp 385-395; Chiba, T. et al., J. Photopolym. Sci. Technol., (200), 13 (4), 657-664; and Hoang, V. T. et al., Macromolecules (2002), 35(17), 6539-6549, all of which are incorporated herein by reference. In light of the disclosure herein and the cited documents, those of skill in the art will be readily able to produce polymers of the present invention without undue experimentation.

Uses of the Polymers

The polymers of the present invention have utility in a wide range of applications.

For example, one embodiment of the present invention relates to the use of the present polymers in photoresist compositions. The polymers of the present invention preferably exhibit beneficial transparency characteristics for a range of UV or other irradiation, including, for example, from about 50 to about 300 nm, most notably at about 157 nanometers, and/or other characteristics that make them particularly suitable for use in photoresist applications.

In certain embodiments, the photoresist compositions of the present invention comprise a polymer of the present invention. The photoresists of the present invention may further comprise a solvent and a photoinitiator (for example, a photosensitive acid generator). Any of a wide range of solvents are suitable for use in the photoresist compositions of the present invention. For example, any of the solvents disclosed in published patent application WO 97/33198 may be used herein. Any of a wide range of photoinitiators are suitable for use in the present photoresist compositions. Examples of suitable photoinitiators include those disclosed in published patent application WO 97/33198. In certain embodiments, the photoinitiator is preferably present in an amount of from about 1 to about 100 weight percent based on the total weight of photoinitiator and polymer (w/w %). More preferably the photoinitiator is present in an amount of about 5 to about 50 w/w % to polymer.

In certain embodiments, the photoresist compositions of the present invention further comprise a dissolution inhibitor. Any of a wide range of known dissolution inhibitors can be used in the practice of the present invention. For example, t-butyl cholate and the like may be used as a dissolution inhibitors in the present photoresist compositions. Any suitable amount of dissolution inhibitor can be used. Preferably, the dissolution inhibitor is used in an amount of up to about 20 weight % of the photoresist composition.

In certain embodiments, the photoresist compositions of the present invention further comprise a sensitizer capable of sensitizing the photoinitiator to longer wavelengths ranging from mid-UV to visible light. Examples of suitable sensitizers are disclosed in WO 97/33198, and U.S. Pat. Nos. 4,250,053; 4,371,605; and 4,491,628, all of which are incorporated herein by reference.

The photoresist compositions of the present invention can be used to generate a positive tone resist image on a substrate. The present invention provides a method for generating a positive tone resist image on a substrate comprising the steps of (a) coating a substrate with a film comprising a photoresist composition of the present invention, (b) exposing the film to radiation, and (c) developing the image. The coating, radiating and developing steps can be performed using known techniques. For example, the procedures described in application WO 97/33198 can be adapted for use in the present invention. In light of the disclosure contained herein, those of skill in the art would be readily able to generate a positive resist image according to the methods of the present invention.

The present invention also relates to an integrated circuit assembly, such as an integrated circuit chip, multichip module, or circuit board made by the process and/or using the polymers of the present invention. The integrated circuit assembly preferably comprises a circuit formed on a substrate by the steps of (a) coating a substrate with a film comprising a photoresist composition of the present invention, (b) exposing the film to radiation, (c) developing the image to expose the substrate, and (d) forming the circuit on the substrate. Any of a wide range of known techniques, including those described in application WO 97/33198, can be adapted for use in the methods of the present invention.

The polymers of the present invention also find use as dielectric, passivation and insulating materials, light guides, anti-reflective coatings and layers, pellicles, glues and the like.

Method for Making Monomer Compounds

The present invention provides efficient methods for producing a wide variety of fluorinated crotonates, fluoroalkyl norbornenes, and fluorinated allyl alcohols in accordance with the present invention. The methods of the present invention are highly advantageous in that one starting material compound can be used to produce a number or crotonates, norbornenes, and allyl alcohols.

For example, according to certain embodiments, the present invention provides for the preparation of a compound selected from the group consisting of fluorinated crotonates, fluoroalkyl norbornenes, and fluorinated allyl alcohols via the reaction scheme (Scheme 1) shown below.

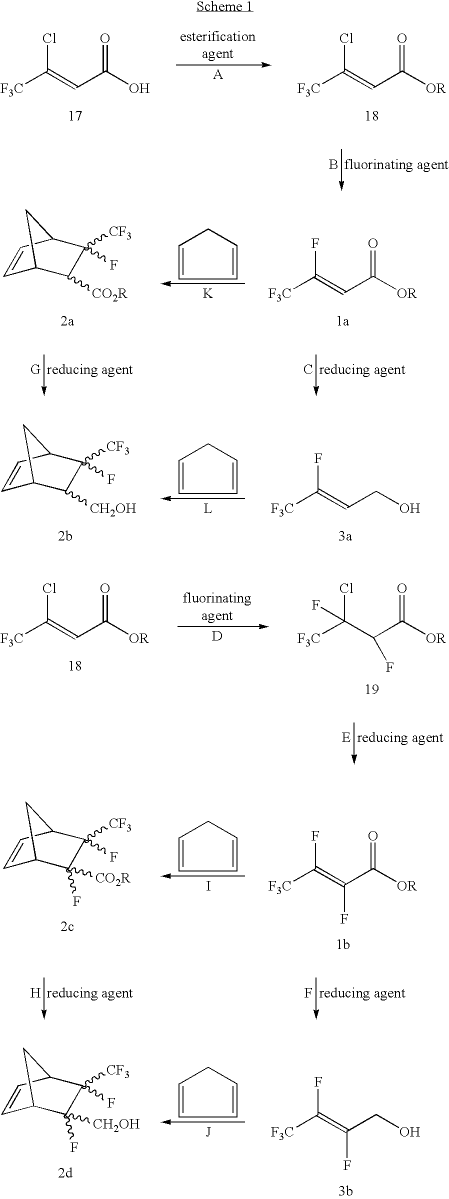

As illustrated in Scheme 1, the present method is flexible and highly adaptable insofar as it allows for the preparation of any of the compounds described by formulae: 1a, 1b, 2a, 2b, 2c, 2d, 3a, and 3b. For example, starting with acid compound 17 and step A shown in Scheme 1, any one or more sequential reaction steps shown in Scheme 1 (labelled steps A-L) can be combined according to the present method to make compounds of the formulae 1a, 1b, 2a, 2b, 2c, 2d, 3a, and 3b. The present methods encompass any of the novel combinations of sequential steps shown in Scheme 1 to produce any compounds described by formulae 1a, 1b, 2a, 2b, 2c, 2d, 3a, and 3b.

The reactants and reaction conditions for step A, and each of the sequential steps (B-J) which can be combined therewith according to certain embodiments of the present method are described below.

Preferably, the esterification step A comprises reacting the acid compound 17 with an esterification agent to form a halogenated crotonate. Syntheses of acid compound 17 are described in the U.S. application Ser. No. 60/259,204, which is incorporated herein by reference (and to which priority is claimed).

As used herein, the term “halogenated crotonate” refers generally to a compound described by formula 18 in Scheme 1. Also, as used herein, the term “esterification agent” refers generally to any reagent that can be reacted with an acid of formula 17 to form a halogenated crotonate of formula 18. Any of a number of esterification agents can be used in the preparation of formula 18 compounds according to the present invention. Examples of suitable esterification agents include isobutene, and those disclosed in Richard C. Larock, Comprehensive Organic Transformations, pages 966-971, (VCH Publishers, Inc 1989), incorporated herein by reference. A preferred esterification agent is isobutene.

The esterification agents can be introduced to the formula 17 compounds to produce compounds of formula 18 under any suitable conditions. Those of skill in the art will recognize that the conditions for any given esterification reaction will depend, at least in part, on the reagents used, and the purity and yield desired. For example, isobutene can be introduced in the presence of acid and tert-butanol to afford a tert-butyl ester as disclosed in Leroy, J.; Journal of Fluorine Chemistry, vol. 53, pages 61-70 (1991), incorporated herein by reference. In addition, the reaction conditions disclosed in Richard C. Larock, Comprehensive Organic Transformations, pages 966-971, (VCH Publishers, Inc 1989) can be adapted for use in the present invention.

Step B is a fluorinating step. Preferably, a halogenated crotonate of formula 18 is reacted with a fluorinating agent to produce a fluorinated crotonate of formula 1a. Any of a wide range of fluorinating agents can be used in the fluorination of a compound of formula 18 including, for example, those disclosed in Richard C. Larock, Comprehensive Organic Transformations, pages 337-345, (VCH Publishers, Inc 1989), incorporated herein by reference. Preferable fluorinating agents include potassium fluoride, potassium bifluoride, and the like. Any suitable reaction conditions can be used to convert the compound of formula 18 to a compound of formula 1a according to the present invention. For example, the reaction conditions disclosed in Chalchat, C.R. Acad. Sc. Paris, vol. 273, pages 764-765 (1971), incorporated herein by reference, and Richard C. Larock, Comprehensive Organic Transformations, pages 337-345, (VCH Publishers, Inc 1989) can be adapted for use herein.

Step C is a reduction step. Preferably, a fluorinated crotonate of formula l a is reacted with a reducing agent to form a fluorinated allyl alcohol of formula 3a. Any of a wide range of reducing agents can be used according to the present invention including, for example, hydrides, such as, lithium aluminum hydride, sodium borohydride, diisobutylaluminum hydride (DIBAL), combinations of hydrides and other reducing agents, such as, lithium aluminum hydride and aluminum trichloride, as well as other reducing agents such as those disclosed in Richard C. Larock, Comprehensive Organic Transformations, pages 548-552, (VCH Publishers, Inc 1989), incorporated herein by reference. Preferable reducing agents include hydrides, such as, lithium aluminum hydride in ether, lithium aluminum hydride and aluminum trichloride in ether, sodium borohydride in polyethylene glycol, and DIBAL in tetrahydrofuran. A particularly preferably reducing agent is lithium aluminum hydride in ether.

Any suitable, known reaction conditions can be used to convert a compound of formula 1a to a compound of formula 3a according to step C of the present invention. In certain preferred embodiments, the reducing agent and starting compound are reacted at a temperature of about 0° C. to about 5° C. Other suitable reaction conditions are disclosed in Richard C. Larock, Comprehensive Organic Transformations, pages 548-552, (VCH Publishers, Inc 1989) which can be adapted for use herein.

Step D is a fluorination step. Preferably, a halogenated crotonate of formula 18 is reacted with a fluorinating agent to produce a halogenated ester of formula 19. Any of a wide range of fluorinating agents can be used according to the present invention including agents disclosed in Richard C. Larock, Comprehensive Organic Transformations, pages 966-971, (VCH Publishers, Inc 1989). A preferred fluorinating agent for use in Step D is molecular fluorine. Any suitable conditions for fluorinating a compound of formula 18 to form a compound of formula 19 can be used in the present method. For example, the conditions disclosed in Sato, Tetrahedron Lett., vol. 36, pages 6705-6708, incorporated herein by reference, and Richard C. Larock, Comprehensive Organic Transformations, pages 966-971, (VCH Publishers, Inc 1989), can be adapted for use herein.

Step E is a dehydrohalogenation step. Preferably, a fluorinated crotonate of formula 19 is reacted with a dehydrohalogenating agent to form a fluorinated crotonate of formula 1b. Any of a wide range of dehydrohalogenating agents are suitable for use in Step E of the present invention. Preferable agents include weak bases, such as, triethylamine. Any of a wide range of suitable reaction conditions can be used according to the present invention. For example, the reaction conditions disclosed in Sato, Tetrahedron Lett., vol. 36, pages 6705-6708, incorporated herein by reference, can be adapted for use herein.

Step F is a reduction step. Preferably a fluorinated crotonate of formula lb is reduced to form a fluorinated allyl alcohol of formula 3b. In general, the suitable reagents and reactions conditions for Step C should be suitable for the instant step.

Steps G and H are reduction steps. Preferably a norbornene of formula 2a or 2c, respectively, is reduced to form a norbornene alcohol of formula 2b or 2d, respectively. In general, the suitable reagents and reactions conditions for Step C should be suitable for the instant step.

Steps I-L are Diels-Alder addition reactions. Preferably, steps I-L comprise reacting a compound of formula 1a, 3a, 1b, or 3b, respectively, with cyclopentadiene to form compounds of formulae 2a, 2b, 2c, or 2d, respectively. Any suitable set of reaction conditions can be used in the practice of the present invention. Temperature, time, and pressure conditions of Diels-Alder reactions are known and are adaptable for use herein. The particular set of reaction conditions used in any given reaction will depend on the particular reactants and catalyst used and the time and yield of product desired. In general, however, the Diels-Alder reactions of the present invention involve stirring a mixture of compound of Formula 2 with freshly distilled cyclopentadiene at 0° C. to 185° C. with or with out a solvent. Cyclopentadiene may be obtained by “cracking” the commercially available dicyclopentadiene (as such process is generally known in the art). Typically, the product is obtained in a 90% yield or greater. A preferred solvent is water; other organic solvents such as ether, tetrahydrofuran, pentane, toluene, dichloromethane and the like can also be used. Preferred reaction temperatures include 0° C. to 35° C. Variation of Diels-Alder reaction conditions, including catalysts, can be employed to optimize the yield. Examples of suitable reaction conditions that can be adapted for use herein are disclosed in J. March, Advanced Organic Chemistry, pages 839-856 (Fourth Ed. 1992), incorporated herein by reference.

According to certain other embodiments, the present invention provides for the preparation of a compound selected from the group consisting of fluorinated crotonates, fluoroalkyl norbornenes, and fluorinated allyl alcohols via the reaction scheme (Scheme 2) shown below.

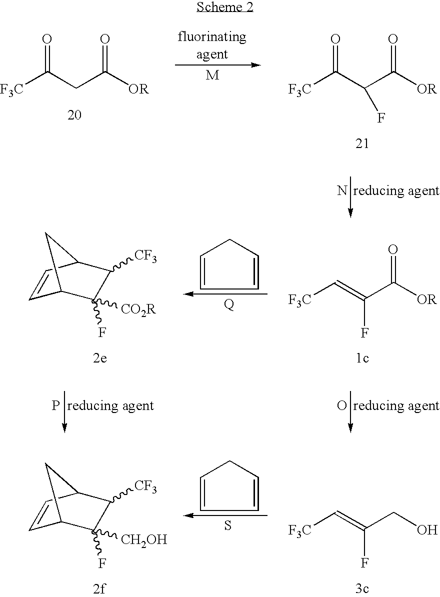

As illustrated in Scheme 2, the present methods are flexible and highly adaptable insofar as they allow for the preparation of any of the compounds described by formulae: 1c, 3c, 2e, and 2f. For example, starting with compound 20 (a number of which, including the t-butyl ester, are commercially available starting material) and step M shown in Scheme 2, any one or more sequential reaction steps shown in Scheme 2 (labelled steps M-Q and S) can be combined according to the present method to make compounds of the formulae 1c, 3c, 2e, and 2f. The present methods encompass any of the novel combinations of sequential steps shown in Scheme 2 to produce any compounds described by formulae 1c, 3c, 2e, and 2f.

The reactants and reaction conditions for step M, and each of the sequential steps (M-Q and S) which can be combined therewith according to certain embodiments of the present method are described below.

Step M is a fluorinating step. Preferably, a compound of formula 20 is reacted with a fluorinating agent to form a compound of formula 21. Any of a wide range of fluorinating agents can be used according to the present invention for step M, including those disclosed in E. Differding, N-Fluorobenzenesulfonimide: A Practical Reagent For Electrophilic Fluorinations, Synlett, March 1991, pages 187-189, incoporated herein by reference. A preferable fluorinating agent is N-Fluorobenzenesulfonimide (NFSI). Those of skill in the art will recognize that the conditions for any given fluorination reaction will depend, at least in part, on the reagents used, and the purity and yield desired. For example, in certain embodiments, the reaction conditions disclosed in E. Differding, N-Fluorobenzenesulfonimide: A Practical Reagent For Electrophilic Fluorinations, Synlett, March 1991, pages 187-189 can be adapted for use herein.

Step N is a reduction step. Preferably, a compound of formula 21 is reacted with a reducing agent to form a compound of formula 1c. Any of a wide range of reducing agents can be used according to the present invention including those disclosed in K,Richard C. Larock, Comprehensive Organic Transformations, pages 527-553, (VCH Publishers, Inc 1989), incorporated herein by reference. A preferred reducing agent is sodium borohydride. Any of a wide range of suitable reaction conditions can be used according to the present invention. Those of skill in the art will recognize that the conditions for any given reduction reaction will depend, at least in part, on the reagents used, and the purity and yield desired. For example, the reaction conditions disclosed in K,Richard C. Larock, Comprehensive Organic Transformations, pages 527-553, (VCH Publishers, Inc 1989) can be adapted for used herein.

Step O is a reduction step similar to steps C and F, described above. The reagents and conditions suitable for use in steps C and F are suitable for use in step O.

Step P is a reduction step similar to steps G and H, described above. The reagents and conditions suitable for use in steps G and H are suitable for use in step P.

Steps Q and S are Diels-Alder addition steps similar to steps I-L, described above. The reagents and conditions suitable for use in steps I-L are suitable for use in steps Q and S.

The compounds of obtained from any of the aforementioned reactions of Schemes 1 and 2 may be purified by conventional methods known to those skilled in the art. For example, aqueous washes, drying, concentrating under reduced pressure, distillation, and the like may be used.

In addition, as will be recognized by those of skill in the art, the compounds obtained in any of the above reaction schemes may be further functionalized or modified to achieve other compounds within the present invention. For example, the acid/ester compounds 2a-2f may be further reduced to produce alcohols or reacted to form differently functionalized carbonyl moieties. According to certain preferred embodiments, an acid/ester compound 2a-2f is reduced to an alcohol using a reducing agent and reducing conditions as described in Step C, above, to produce an alcohol of Formula 3, according to the present invention.

In light of this disclosure, those of skill in the art will be readily able to select appropriate reagents and optimize reaction conditions for each of the reaction steps described above without undue experimentation.

### EXAMPLES

In order that the invention may be more readily understood, reference is made to the following examples which are intended to be illustrative of the invention, but are not intended to be limiting in scope.

### Example 1

This example illustrates the preparation of Ethyl 3-(trifluoromethyl)-bicyclo[2.2.1]hept-5-ene-2-carboxylate via a Diels-Alder reaction in a solvent according to the present invention.

To a reaction vessel containing a stirred mixture of 4,4,4-trifluorocrotonate ethyl ester, CF₃(H)C═C(H)CO₂C₂H₅, (50 g) in 1.7 L de-ionized water at 10° C. is added 20g of freshly distilled cyclopentadiene. The resulting reaction mixture is stirred at 10° C. for about 10 hours. The product is separated, and the organic layer distilled at 71-86° C./1-3 mmHg to afford 57.0 g (82% yield) of the product as a clear liquid. NMR and MS spectral data are consistent with the structure.

### Example 2

This example illustrates the preparation of Ethyl 3-(trifluoromethyl)-bicyclo[2.2.1]hept-5-ene-2-carboxylate via a Diels-Alder reaction without solvent according to the present invention.

The reaction is carried out as in Example 1, except that no solvent is used. Crude product is distilled to afford 58.0 g (83% yield) of purified product.

### Example 3

This example illustrates the preparation of Ethyl 3,3-bis(trifluoromethyl)-bicyclo[2.2.1]hept-5-ene-2-carboxylate via a Diels-Alder reaction in solvent according to the present invention.

A mixture of ethyl-3,3-bis(trifluoromethyl)-2-butenoate (16.5 g), 75 ml deionized water, and freshly cracked cyclopentadiene (4.5 g) was stirred at 6-8° C. for 72 h. The lower layer was then separated and distilled at 90-92° C./5 mm Hg to afford 8.5 g (40% yield) of product. Spectral data are consistent with the structure.

GC/MS: m/e 302 for M⁺ for C₁₂H₁₂F₆O₂; ¹⁹F NMR δ −60.5 (dq, 3F) and −65 (dq, 3F) ppm.

### Example 4

This example illustrates the preparation of Ethyl 3,3-bis(trifluoromethyl)-bicyclo[2.2.1 ]hept-5-ene-2-carboxylate via a Diels-Alder reaction without solvent according to the present invention.

A mixture of ethyl-3,3-bis(trifluoromethyl)-2-butenoate (5g, 21 mmol), and freshly distilled cyclopentadiene (1.36 g, 21 mmol) was stirred at 10-12° C. for 17 h. The reaction mixture was concentrated under reduced pressure and distilled at 90-92° C./5 mm Hg to afford 4.2 g (66 % yield) ethyl 3,3-bis(trifluormethyl)bicyclo[2.2.1 ]hept-5-ene-2-carboxylate.

### Example 5

This example illustrates the preparation of tert-butyl 3-fluoro-3-trifluoromethyl)bicyclo[2.2.1]hept 5-en-2-carboxylate via a Diels-Alder reaction according to the present invention.

A mixture of CF₃(F)C═C(H)C(O)OC(CH₃)₃ ( 6 g ), freshly distilled cylopentadiene (2 g) and de-ionized water (300 mL) was stirred at 10° C. for 16 hours. The lower layer was separated and distilled at 62° C. /21 mm Hg to afford 4 g (50% yield) of tert-butyl 3-fluoro-3-(trifluoromethyl)bicyclo[2.2.1]hept-5-en-2-carboxylate as a colorless liquid. Spectral data are consistent with the structure.

### Examples 6-13

This example illustrates the preparation of a number of compounds of Formula 1 via a Diels-Alder reaction according to the present invention.

Eight (8) different dienophile compounds (E6-E13 as shown in Scheme 3 below) are individually reacted as in Example 1 with an approximately equal molar amount of fresh cyclopentadiene in the presence of an excess amount of distilled water to afford their respective norbornene product compounds (as shown in Scheme 3).

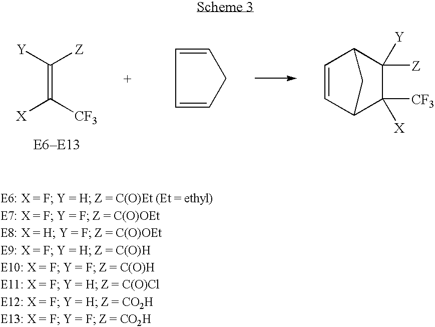

### Examples 14-21

This example illustrates the preparation of a number of compounds of Formula 1 via a Diels-Alder reaction without solvent according to the present invention.

Eight (8) different dienophile compounds (E6-E13 as shown in Scheme 3) were individually reacted as in Example 2 with an approximately equal molar amount of fresh cyclopentane to afford their respective norbornene product compounds (as shown in Scheme 3).

### Example 22

This example illustrates the preparation of 3-(Trifluoromethyl)bicyclo[2.2.1]hept-5-en-2-yl-methan-1-ol via a norbornene ester reduction reaction according to the present invention.

Under nitrogen purge, to 75 mL dry ether at 0° C. was added AlCl₃ ( 4.8 g, 36 mmol). After stirring for 5 minutes, lithium aluminum hydride ( 4.06 g, 107 mmol) was added via a solid addition funnel in such a way that the temperature did not rise>4° C. The reaction mixture was stirred for 15 minutes at this temperature and 3-(trifluoromethyl)bicyclo[2.2.1]hept-5-ene-2-carboxylate (10 g, 42.7 mmol) in 30 mL dry ether was added drop-wise such a way that the temperature did not rise>4° C.. [Caution! Exothermic]. After complete addition the reaction mixture was stirred at 0° C. for 2 hours, quenched (˜40 mL) with sat. solution of Na₂SO₄ [Caution!! Exothermic] and 100 ml water and 50 mL ether was added. The ether layer was separated and aq. layer was extracted with 2×30 mL ether. The combined ether layers were dried (MgSO₄) and concentrated. The crude product was distilled (70-72° C./ 2mm Hg) via short vigreux column to afford the alcohol (5.5 g, yield, 67 %) as a clear liquid.

GC/MS (EI mode): m/e 192 for M⁺ for C₉H₁₁F₃O; ¹⁹F NMR δ −66.5 (d) and −67.9 (d) ppm in the ratio 82:16 for two isomers. ¹H spectrum is consistent with the structure.

### Example 23

This example illustrates the preparation of 3-(Trifluoromethyl)bicyclo[2.2.1 ]hept-5-en-2-yl]methan-1-ol via a reduction reaction according to the present invention.

Under nitrogen purge, to a stirred mixture of 500 mL dry ether and 16.2 g (0.43 mol) LiAlH₄ at 0° C., was added drop-wise 3-(trifluoromethyl)bicyclo[2.2.1]hept-5-ene-2-carboxylate (100 g, 0.43 mmol) in 75 ml dry ether. The addition was such that the temperature was ≦10° C. After stirring for 1 hr at at 5-7° C. the reaction mixture was brought to room temperature and stirred for ˜3 hours. After this, the reaction mixture was cooled to ˜0° C. and water (20 mL), 20 mL 15% aq. sodium hydroxide solution, and water (60 mL) were added sequentially in such a way that the temperature was maintained ≦10° C. The reaction mixture was filtered, extracted with 500 ml ether, washed with brine (2×25 ml), dried (MgSO₄), concentrated, and distilled to afford the product (73.8 g, yield=90%) as a clear liquid.

### Example 24

This example illustrates the preparation of 3,3 -bis(trifluoromethyl)bicyclo [2.2.1]hept-5-en-2-yl]methan-1-ol via a reduction reaction according to the present invention.

To a 250 mL round bottom flask was added 1.8 g lithium aluminum hydride (LAH) (1.8 g, 48 mmol) under nitrogen atmosphere. The flask was cooled to ˜5° C. and 50 mL anhydrous ether was added. The LAH in ether was stirred for 5 minutes at this temperature and ethyl 3,3-bis(trifluormethyl)bicyclo[2.2.1]hept-5-ene-2-carboxylate (10.7 g, 35.4 mmol) in 15 mL dry ether was added drop-wise in such a way that the temperature did not rise>8° C. (Caution! Exothermic). After complete addition, the reaction mixture was stirred at ˜5° C. for 1 hour. Then the reaction mixture was cooled to ˜0° C. and quenched by slow addition of water (6 mL) followed by 6 mL 20% solution of sodium hydroxide. 50 mL ether and 6 ml water was added to the stirred reaction mixture and brought to room temperature. The ether layer was separated and aq. layer was extracted with 2×20 mL ether. The combined ether layer was washed with brine 10 ml, dried (MgSO₄), and concentrated under reduced pressure. Removal solvent at 2 mm Hg at 35° C. afforded product as a white powder (7.25 g, yield 79%), mp 64-66° C. Spectral data are consistent with the structure.

GC/MS: m/e 260 for M⁺ for C₁₀H₁₀F₆O; ¹⁹F NMR (CDCl₃) δ −61.2 (q, 3F, J=14 Hz) and −62.3 (q, 3F, J=13 Hz) ppm for isomer 1; −57.4(3F, q, J=12 Hz), −67.2(3F, q, J=12 Hz) ppm for isomer 2; the ratio of isomers is 3:1. ¹H spectrum is consistent with the structure.

### Examples 25-30

This example illustrates the preparation of a number of alcohol compounds of Formula 1 via a reduction reaction according to the present invention.

Six (6) norbornene ester compounds (E25-E30 as shown in Scheme 4 below) are individually reacted as in Example 23 with LAH to afford their respective norbornene alcohol product compounds (as shown in Scheme 4).

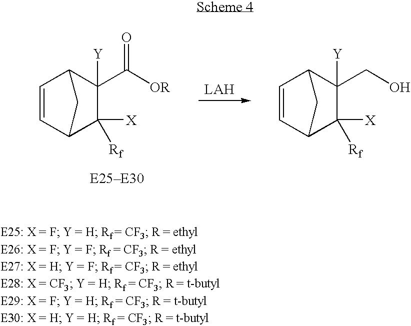

### Example 31

This example illustrates the polymerization of a norbornene monomer of the present invention to form a polymer of the present invention.

To a 50 mL glass via equipped with a Teflon coated stir bar is added a monomer compound 2-methylpropyl-3-fluoro-3-(trifluoromethyl)-bicyclo[2.2.1 ]hept-5-ene-2-carboxylate (10.3 mmol). The monomer compound is stirred at ambient temperature and to the stirred compound is added a catalyst solution. (The catalyst solution is prepared by adding η3-allylpalladium chloride dimer (38 mg, 0.1 mmol) in 5 mL chlorobenzene to silver hexafluoroantimonate (99 mg, 0.3 mmol) in 5 mL chlorobenzene for 30 minutes and then filtering through a micropore filter to remove precipitated silver chloride). The reaction is allowed to run for 36 hours. After this time, the mixture has gelled to form a clear yellow gel. Upon adding the gel to excess methanol, the polymer precipitates as a white powder. The polymer is washed with excess methanol and dried.

### Example 32

This example illustrates the polymerization of a norbornene monomer of the present invention to form a polymer of the present invention.

In a dry box, to a 100 mL round bottom flask equipped with a stir bar are added, η3-allylpalladium chloride dimer (3.7 mmol) and silver hexafluorantimonate (7.3 mmol). After addition of 50 mL dry dichloromethane, the mixture is stirred at room temperature for 20 minutes. This reaction mixture is filtered via 0.45 mm syringe filter to a 100 mL flask containing a compound of Formula 2 (73 mmol) in 50 mL dichlormethane. The reaction mixture is stirred at room temperature for 24 hours, then precipitated into hexanes (2L). The light cream colored powder is collected via filtration and dried to afford a homopolymer. Further purification is done by treatment with activated carbon, filtration and drying.

### Example 33

This example illustrates the co-polymerization of two norbornene monomers of the present invention to form a polymer of the present invention.

To a 50 mL flask equipped with a Teflon coated stir bar is added (η⁶-toulene) bis(pentafluorophenyl)nickel(II) (49 mg, 0.103 mmol) and toluene (10 mL) under an inert atmosphere(argon). Monomers 3 -(Bicyclo[2.2.1]hept-5-en-2-yl) 1,1,1-trifluoro-2(trifluoromethyl)propanaol (NBHFA) (2.12 g, 7.73 mmol) and 3-(Trifluoromethyl)bicyclo[2.2.1]hept-5-en-2-yl]methan-1-ol (2.58 mmol) are added to a Schlenk tube and degassed by three freeze-pump-thaw cycles. The toluene solution containing the catalyst solution is transferred via canula to the Schlenk tube, and the mixture is stirred for 24 hours. The resultant solution is poured into 500 mL methanol, and the white polymer is filtered and dried to afford 1.6 g of the desired polymer.

What is claimed is:

1. A polymer comprising a repeating unit derived from a compound selected from the group consisting of:
(A) fluoroalkyl norbornenes of formula 1 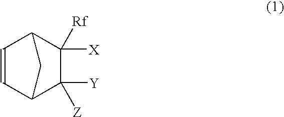
wherein X and Y are independently hydrogen, fluorine, or fluorinated alkyl; R_{f} is a fluorinated alkyl group; Z is —CH₂OH, —CO₂R, or —C(O)R₁; R is an alkyl group; and R₁ is hydrogen, hydroxyl, halogen, or nitrile;
(B) fluorinated crotonates of formula 2 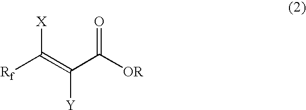
wherein X and Y are independently hydrogen, fluorine, or fluorinated alkyl; R_{f} is a fluorinated alkyl group; Z is —CH₂OH, —CO₂R, or —C(O)R₁; R is an alkyl group; and R₁ is hydrogen, hydroxyl, halogen, or nitrile;
(C) fluorinated allyl alcohols of formula 3 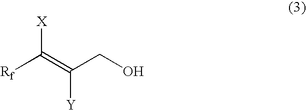
wherein X and Y are independently hydrogen, fluorine, or fluorinated alkyl; R_{f} is a fluorinated alkyl group; Z is —CH₂OH, —CO₂R, or —C(O)R₁; R is an alkyl group; and R₁ is hydrogen, hydroxyl, halogen, or nitrile; and
(D) combinations of two or more thereof.

2. The polymer of claim 1 comprising at least one repeating unit derived from a fluoroalkyl norbornene of formula 1.

3. The polymer of claim 2 wherein said repeating unit is derived from a compound of formula 1 wherein X═R_{f}.

4. The polymer of claim 2 wherein said repeating unit is derived from a compound of formula 1 wherein Y═R_{f}.

5. The polymer of claim 2 wherein said repeating unit is derived from a compound of formula 1 wherein X═Y═R_{f}.

6. The polymer of claim 2 wherein said repeating unit is derived from a compound of formula 1 wherein R_{f} is trifluoromethyl and Z is CO₂R.

7. The polymer of claim 2 wherein said repeating unit is derived from a compound of formula 1 wherein R_{f} is trifluoromethyl and Z is CH₂OH.

8. The polymer of claim 2 wherein said fluoroalkyl norbornene is selected from the group consisting of: 2-methylpropyl-3-fluoro-3-(trifluoromethyl)-bicyclo[2.2.1 ]hept-5-ene-2-carboxylate, 2-methylpropyl-2,3-difluoro-3-(trifluoromethyl)-bicyclo[2.2.1]hept-5-ene-2-carboxylate, 2-methylpropyl-2-fluoro-3-(trifluoromethyl)-bicyclo[2.2.1 ]hept-5-ene-2-carboxylate, 2-methylpropyl-3-(trifluoromethyl)-bicyclo[2.2.1 ]hept-5-ene-2-carboxylate, 3-(trifluoromethyl)-2-hydroxymethyl-bicyclo[2.2.1 ]hept-5-ene-2-carboxylate, 3-fluoro-3 -(trifluoromethyl)-2-hydroxymethyl-bicyclo[2.2.1 ]hept-5-ene-2-carboxylate, 2-fluoro-3-(trifluoromethyl)-2-hydroxymethyl-bicyclo[2.2.1]hept-5-ene-2-carboxylate, and 2,3-difluoro-3-(trifluoromethyl)-2-hydroxymethyl-bicyclo[2.2.1 ]hept-5 -ene-2-carboxylate.

9. The polymer of claim 1 comprising at least one repeating unit derived from a fluorinated crotonate of formula 2.

10. The polymer of claim 9 wherein said at least one repeating unit is derived from a fluorinated crotonate wherein R_{f} is trifluoromethyl.

11. The polymer of claim 9 wherein said fluorinated crotonate is selected from the group consisting of 3,4,4,4-tetrafluoro-but-2-enoic acid t-butyl ester, 2,3,4,4,4-pentafluoro-but-2-enoic acid t-butyl ester, 2,4,4,4-tetrafluoro-but-2-enoic acid t-butyl ester, and 4,4,4-trifluoro-but-2-enoic acid t-butyl ester, and combinations of two or more thereof.

12. The polymer of claim 1 comprising at least one repeating unit derived from a fluorinated allyl alcohol of formula 3.

13. The polymer of claim 12 wherein said at least one repeating unit is derived from a fluorinated allyl alcohol wherein R_{f} is trifluoromethyl.

14. The polymer of claim 12 wherein said compound is selected from the group consisting of 4,4,4-trifluoro-but-2-en-1-ol, 3,4,4,4-tetrafluoro-but-2-en-1-ol, 2,4,4,4-tetrafluoro-but-2-en-1-ol, 2,3,4,4,4-pentafluoro-but-2-en-1-ol, and combinations of two or more thereof.

15. The polymer according to claim 1, further comprising repeating units derived from an ethylenically unsaturated compounds selected from the group consisting of CF₃CH═CF₂; CF₃CH═CHF; CF₃CF═CHF; CF₃CF═CH₂; CF₂═CH₂; CF₂═CFH; CF₂═CF₂; R_{pf}CH₂)ₙCV═CVW wherein R_{pf} is a perfluoroalkyl group having from about 1 to about 10 carbon atoms, V and W are indepedently H or F, provided that when R_{f} is CF₃ and V is F, W must be H, and mixtures of two or more thereof.

16. A photoresist composition comprising a polymer according to claim 1.

17. The photoresist composition of claim 16 further comprising a solvent and a photoinitiator.

18. The photoresist composition of claim 16 further comprising a dissolution inhibitor.

19. The photoresist composition of claim 16 further comprising a sensitizer.

20. A method for generating a positive tone resist image on a substrate comprising the steps of (a) coating a substrate with a film comprising a photoresist composition of claim 16, (b) exposing the film to radiation, and (c) developing the image.

21. The method of claim 20 wherein said radiation is in the range of from about 50 mn to about 300 nm.

22. An integrated circuit assembly comprising a circuit formed by the steps of:
(a) coating a substrate with a film comprising a photoresist composition of claim 16,
(b) exposing the film to radiation,
(c) developing the image to expose the substrate, and
(d) forming a circuit on the substrate.

23. A light guide comprising a polymer according to claim 1.

24. An anti-reflective coating comprising a polymer according to claim 1.

25. A pellicle comprising a polymer according to claim 1.

26. A glue comprising a polymer according to claim 1.

27. A method for making a compound selected from the group consisting of fluorinated crotonates, fluoroalkyl norbornenes, and fluorinated allyl alcohols comprising the steps of:
(a) reacting the acid compound described by the formula: 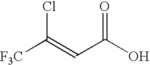
with an esterification agent to form a halogenated crotonate; and
(b) converting said halogenated crotonate to a compound selected from the group consisting of fluorinated crotonates, fluoroalkyl norbornenes, and fluorinated allyl alcohols.

28. The method of claim 27 wherein said converting step (b) comprises reacting said halogenated crotonate with a fluorinating agent to form a fluorinated crotonate.

29. The method of claim 28 wherein said method further comprises the step of reacting said fluorinated crotonate with cyclopentane to form a fluorinated norbornene ester compound.

30. The method of claim 28 wherein said method further comprises the step of reacting said fluorinated norbornene ester compound with a reducing agent to form a fluorinated norbornene alcohol compound

31. The method of claim 29 further comprising the step of reacting said fluorinated crotonate with a reducing agent to form a fluorinated allyl alcohol.

32. The method of claim 31 further comprising the step of reacting said fluorinated allyl alcohol with cyclopentadiene to form a norbornene compound.

33. The method of claim 27 wherein said converting step (b) comprises (i) reacting said halogenated crotonate with a fluorinating agent to form a halogentated ester; and (ii) reacting said halogenated ester with a reducing agent to form a fluorinated crotonate.

34. The method of claim 33 wherein said method further comprises the step of reacting said fluorinated crotonate with cyclopentane to form a fluorinated norbornene ester compound.

35. The method of claim 28 wherein said method further comprises the step of reacting said fluorinated norbornene ester compound with a reducing agent to form a fluorinated norbornene alcohol compound.

36. The method of claim 33 further comprising the step of reacting said fluorinated crotonate with a reducing agent to form a fluorinated allyl alcohol.

37. The method of claim 36 further comprising the step of reacting said fluorinated allyl alcohol with cyclopentadiene to form a norbornene compound.

38. A method for making a compound selected from the group consisting of fluorinated crotonates, fluoroalkyl norbornenes, and fluorinated allyl alcohols comprising the steps of:
(a) reacting a compound described by the formula: 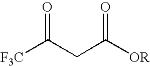
with a fluorinating agent to form a halogenated ester; and
(b) converting said halogenated ester to a compound selected from the group consisting of fluorinated crotonates, fluoroalkyl norbornenes, and fluorinated allyl alcohols.

39. The method of claim 38 wherein said converting step (b) comprises reacting said halogenated ester with a fluorinating agent to form a fluorinated crotonate.

40. The method of claim 39 wherein said method further comprises the step of reacting said fluorinated crotonate with cyclopentane to form a fluorinated norbornene ester compound.

41. The method of claim 40 wherein said method further comprises the step of reacting said fluorinated norbornene ester compound with a reducing agent to form a fluorinated norbornene alcohol compound.

42. The method of claim 40 further comprising the step of reacting said fluorinated crotonate with a reducing agent to form a fluorinated allyl alcohol.

43. The method of claim 42 further comprising the step of reacting said fluorinated allyl alcohol with cyclopentadiene to form a norbornene compound.
